(19) United States
(12) Patent Application Publication
(10) Pub. No.: US 2021/0203320 A1
(43) Pub. Date: Jul. 1, 2021

(54) INPUT CIRCUIT

(71) Applicant: KABUSHIKI KAISHA TOKAI-RIKA-DENKI-SEISAKUSHO, Aichi-ken (JP)

(72) Inventor: Keigo Kagimoto, Aichi-ken (JP)

(21) Appl. No.: 17/126,823

(22) Filed: Dec. 18, 2020

(30) Foreign Application Priority Data
Dec. 26, 2019 (JP) 2019-237410

(51) Int. Cl. H03K 17/687; G05F 3/26; H03F 3/345

(52) U.S. Cl. CPC H03K 17/687; H03F 3/345; G05F 3/262

(57) ABSTRACT

An input circuit including an input transistor including a drain input with an input voltage, an input current generation circuit configured to generate an input current to flow in the input transistor, a resistor connected between a source of the input transistor and a first power source, and an output transistor including a gate connected to a connection point between the source of the input transistor and the resistor.

### CROSS-REFERENCE TO RELATED APPLICATION

This application is based on and claims priority under 35 USC 119 from Japanese Patent Application No. 2019-237410 filed on Dec. 26, 2019, the disclosure of which is incorporated by reference herein.

### BACKGROUND

### Technical Field

The present disclosure relates to an input circuit.

In semiconductor integrated circuits operated by a high voltage power source and a low voltage power source, a dynamic range of an input voltage sometimes becomes an issue when there is a level shift in the input voltage. A semiconductor integrated circuit disclosed in Japanese Patent Application Laid-Open (JP-A) No. 2000-58671 is a known example of technology relating to this issue. In the semiconductor integrated circuit according to JP-A No. 2000-58671, the semiconductor integrated circuit includes a level shift circuit and an output stage circuit. The level shift circuit is configured by an n-channel MOSFET and a p-channel MOSFET, and n-channel MOSFETs are employed on a high side and on a low side of the output stage circuit. A resistor and a diode are arranged between a gate and source of the n-channel MOSFET on the high side, such that a cathode of the diode is connected to the gate of the high side n-channel MOSFET and an anode of the diode is connected to the source thereof. Due to adopting the above configuration in JP-A No. 2000-58671, a small size and low energy consumption semiconductor integrated circuit can be realized that includes a level shift circuit and an output stage circuit.

Explanation follows regarding an example of related art in which a dynamic range of an input circuit has been expanded while transistor withstand voltage conditions are satisfied, with reference to FIG. 3. FIG. 3 is a circuit diagram illustrating an input circuit 100 according to related art. As illustrated in FIG. 3, the input circuit 100 is configured including N-type metal oxide semiconductor (MOS) transistors QN11, QN12, a P-type MOS transistor QP11, resistors R11, R12, R13, and an inverter IN2. The input circuit 100 includes a section operated by a high voltage power source VBB having a relatively high voltage value, and a section operated by a low voltage power source VCC having a relatively low voltage value. The input circuit 100 includes an input voltage level shift function.

In the input circuit 100, an input voltage Vin and a threshold voltage of the P-type MOS transistor QP11 are compared so as to determine whether the input voltage Vin is low level (hereafter referred to as “L”) or high level (hereafter referred to as “H”). A current I3 flows in the P-type MOS transistor QP11 in response to the level of the input voltage Vin (i.e. when the input voltage Vin is L). The N-type MOS transistors QN11 and QN12 configure a current mirror to mirror the current I3 such that a current corresponding to the current I3 flows in the resistor R13. An output voltage Vout is generated according to the voltage descend by the resistor R13 as output through the inverter IN2.

The resistors R11, R12 divide the input voltage Vin according to operation conditions and so on of the input circuit 100, and function so as to reduce the voltage input to the P-type MOS transistor QP11. However, when the input voltage Vin is L, the P-type MOS transistor QP11 being ON is another condition for voltage dividing. A diode D1 as illustrated in FIG. 3 is also sometimes employed to regulate a voltage level input to a gate of the P-type MOS transistor QP11. Logical switching of the input voltage Vin is schematically illustrated by a switch SW2.

Consider a case in which a full swing of the input voltage Vin is between ground and a voltage value of the high voltage power source VBB. Current does not flow through the resistors R11, R12 in the input circuit 100 when the input voltage Vin is H, and so a gate-source voltage Vgs of the P-type MOS transistor QP11 is 0V, and the P-type MOS transistor QP11 is not ON. Namely, the output voltage Vout is L. However, when the input voltage Vin is L, a current calculated by (VBB−Vin)/(R11+R12) flows through the resistors R11, R12, and a voltage of R11·(VBB−Vin)/(R11+R12) divided by the resistors R11, R12 is applied between the gate and source of the P-type MOS transistor QP11. The gate-source voltage Vgs is set so as to be a threshold voltage of the P-type MOS transistor QP11 or greater, and so when this occurs the P-type MOS transistor QP11 is ON and the output voltage Vout is H.

Cases may arise in which there is a desire to change the voltage applied to the high voltage power source VBB in response to conditions of use and so on of the power source voltage. Operation of the input circuit 100 when this is performed is considered below, with reference to specific values. Suppose that the diode D1 is not connected, the voltage value of the high voltage power source VBB is 4V, and the voltage division ratio R11:R12 is set to 1:3. Suppose also that a gate-source withstand voltage <Vgs> of the P-type MOS transistor QP11 is set to 5V, and that a threshold voltage of the gate-source voltage Vgs is 1V. In such a case, when the input voltage is L, the gate-source voltage Vgs of the P-type MOS transistor QP11 is 1V and so the P-type MOS transistor QP11 is ON. The gate-source withstand voltage <Vgs> is also not being exceeded and so there are no issues in relation to the withstand voltage.

However, when the voltage of the high voltage power source VBB is changed to 24V, the gate-source voltage Vgs of the P-type MOS transistor QP11 is now 6V. Thus although the P-type MOS transistor QP11 is ON, the gate-source withstand voltage <Vgs> is being exceeded and so not able to configure a circuit. Namely, if the voltage division ratio of the resistors R11, R12 is determined such that the withstand voltage conditions are satisfied for a low voltage value condition of the high voltage power source VBB and so that logical switching of the input voltage Vin can be detected by the P-type MOS transistor QP11, sometimes the withstand voltage conditions is no longer able to be satisfied when the voltage value of the high voltage power source VBB is increased. An approach to resolve this issue is to adopt a configuration as illustrated in FIG. 3 in which a diode D1 (a Zener diode is illustrated as an example in FIG. 3) is connected between the gate and source of the P-type MOS transistor QP11 so as to clamp the input voltage Vin and ensure the gate-source voltage Vgs of the P-type MOS transistor QP11 satisfies the gate-source withstand voltage <Vgs> condition. However, a diode forming process is not always included in fabrication processes for a semiconductor integrated circuit, and so there is no guarantee that a diode can be employed. A circuit configuration not including a diode is accordingly preferable.

### SUMMARY

In consideration of the above circumstances, exemplary embodiments of the present disclosure relate to the provision of an input circuit capable of achieving both an easing withstand voltage-related constraints and an expansion of input dynamic range.

An input circuit according to a first aspect of the present disclosure includes an input transistor including a drain input with an input voltage, an input current generation circuit configured to generate an input current to flow in the input transistor, a first resistor connected between a source of the input transistor and a first power source, and an output transistor including a gate connected to a connection point between the source of the input transistor and the first resistor.

In the input circuit according to the first aspect, the input voltage is input to the drain of the input transistor, and the gate of the output transistor is connected to the connection point between the source of the input transistor and the first resistor. This accordingly enables provision of an input circuit capable of achieving both an easing of the withstand voltage-related constraints and an expansion in input dynamic range.

In an input circuit according to a second aspect of the present disclosure, the input current generation circuit is configured by a current mirror circuit including a first transistor having a gate commonly connected to a gate of the input transistor, and a current source connected to a drain of the first transistor.

In the input circuit according to the second aspect, due to operating as a current mirror circuit, the same current flows in the input transistor as the current flowing in the first transistor. This enables the current flowing in the input transistor to be made constant.

The input circuit according to a third aspect and a fourth aspect of the present disclosure further includes a level shift circuit including a current mirror circuit configured by a second transistor having a drain commonly connected to a drain of the output transistor and a third transistor having a gate commonly connected to a gate of the second transistor, and a second resistor connected between a drain of the third transistor and a second power source having a lower voltage value than a voltage value of the first power source.

In the input circuit according to the third aspect and the fourth aspect, the level shift circuit is configured including the current mirror circuit configured by the second transistor having a drain commonly connected to the drain of the output transistor and the third transistor having a gate commonly connected to the gate of the second transistor, and the second resistor connected between the drain of the third transistor and the second power source having a lower voltage value than the voltage value of the first power source. This enables a simple configuration to be adopted for a level shift circuit.

The embodiments of the present disclosure exhibit the excellent advantageous effects of enabling provision of an input circuit capable of achieving both an easing of the withstand voltage-related constraints and an expansion in input dynamic range.

### BRIEF DESCRIPTION OF DRAWINGS

FIG. 1 is a circuit diagram illustrating an example of a configuration of an input circuit according to an exemplary embodiment of the present disclosure;

FIG. 2 is a circuit diagram illustrating currents in respective sections of an input circuit according to an exemplary embodiment of the present disclosure; and

FIG. 3 is a circuit diagram illustrating a configuration of an input circuit according to related art.

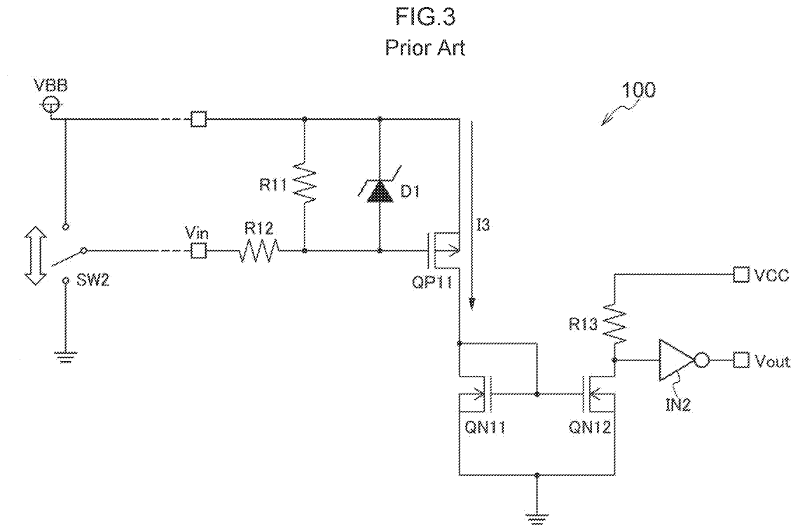

### DETAILED DESCRIPTION

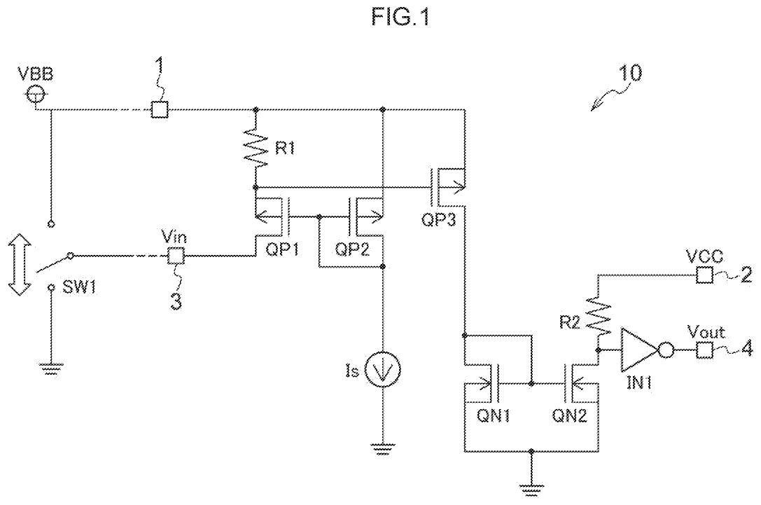

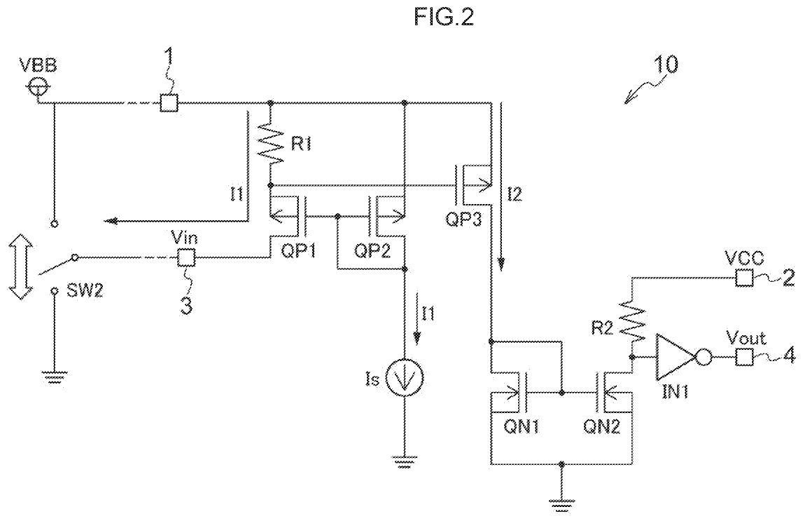

Detailed explanation follows regarding an input circuit 10 according to an exemplary embodiment of the present disclosure, with reference to FIG. 1 and FIG. 2. FIG. 1 is a circuit diagram of the input circuit 10, and FIG. 2 illustrates currents in respective sections of the input circuit 10. The input circuit 10 is for example a circuit for determining a logic level (H, L) of input voltage to a semiconductor integrated circuit.

As illustrated in FIG. 1, the input circuit 10 according to the present exemplary embodiment is configured including N-type MOS transistors QN1, QN2, P-type MOS transistors QP1, QP2, QP3, a current source is, an inverter IN1, and resistors R1, R2. A high voltage power source VBB having a comparatively high voltage value is connected to a terminal 1, and a low voltage power source VCC having a comparatively low voltage value is connected to a terminal 2. An input voltage Vin is input to a terminal 3, and an output voltage V out is output from a terminal 4.

The input voltage Vin according to the present exemplary embodiment has a full swing between ground and the voltage value of the high voltage power source VBB, namely between L=0V and H=VBB. Note that VBB is the voltage value of the high voltage power source. The P-type MOS transistors QP2, QP3 and the resistor R1 are connected to the high voltage power source VBB, and the resistor R2 and the inverter IN1 are connected to the low voltage power source VCC. Logical switching of the input voltage Vin is schematically illustrated by a switch SW1. Note that the P-type MOS transistor QP1 is an example of an input transistor and the P-type MOS transistor QP3 is an example of an output transistor according to the present disclosure.

The input circuit 10 is configured such that the input voltage Vin is input to a drain of the P-type MOS transistor QP1. The P-type MOS transistors QP1 and QP2 configure a current mirror, and so when I1 is the current of the current source Is as illustrated in FIG. 2, the current I1 also flows in the P-type MOS transistor QP1 in response to the input voltage Vin. Namely, when the input voltage Vin is H, Vin=VBB, and so the current I1 does not flow. However, when the input voltage Vin is L, Vin=0V as the drain of the P-type MOS transistor QP1 is connected to ground, and so the current I1 flows.

Thus, when the input voltage Vin is L, a voltage expressed by I1·R1 is applied between gate and source of the P-type MOS transistor QP3. Taking Vt as a threshold of a gate-source voltage of the P-type MOS transistor QP3, the present exemplary embodiment is set such that I1·R1>Vt. Thus, when the input voltage Vin is L, a current I2 flows in the P-type MOS transistor QP3 as illustrated in FIG. 2. Note that although a mirror ratio of the current mirror circuit configured by the P-type MOS transistors QP1 and QP2 is 1:1 in the present exemplary embodiment, there is no limitation thereto, and the minor ratio may be changed according to the design conditions and so on of the input circuit 10. Note that the current mirror circuit configured by the P-type MOS transistors QP1, QP2 and the current source Is is an example of an input current generation circuit according to the present disclosure.

The N-type MOS transistors QN1 and QN2 also configure a current mirror. Thus, when the current I2 flows in the N-type MOS transistor QN1, a current corresponding to I2 (for example, I2 for a mirror ratio of 1:1) flows through the resistor R2, and the output voltage Vout is generated and output from the terminal 4 through the inverter IN1. Note that the current mirror circuit configured by the N-type MOS transistors QN1, QN2 and the resistor R2 configure an example of a level shift circuit according to the present disclosure.

Note that as previously described, for input circuits it is difficult to achieve both an easing of conventional withstand voltage-related constraints and an expansion of an input dynamic range. In order to address this issue, in the input circuit 10 according to the present exemplary embodiment, the input voltage Vin is input to the drain of the P-type MOS transistor QP1 configuring an input transistor. In such cases, the withstand voltage of the P-type MOS transistor QP1 is restricted by a drain-source withstand voltage <Vds> of the P-type MOS transistor QP1. However, this drain-source withstand voltage <Vds> is generally higher than a gate-source withstand voltage <Vgs>. For example, in contrast to a gate-source withstand voltage <Vgs> of approximately 5V, the drain-source withstand voltage <Vds> exhibits a value of approximately 40V. This accordingly enables both an easing of the withstand voltage-related constraints of the P-type MOS transistor QP3 configuring the input transistor, and an expansion in the input dynamic range by raising the voltage value of the high voltage power source VBB, to be accommodated.

Furthermore, the input circuit 10 according to the present exemplary embodiment is configured such that an electric potential of the gate of the P-type MOS transistor QP3 configuring an output transistor is fixed, irrespective of the voltage value of the high voltage power source VBB and irrespective of the input voltage Vin. Namely, as described above, the electric potential of the gate of the P-type MOS transistor QP3 in the input circuit 10 is fixed at (VBB−R1·I1), and so the gate-source voltage Vgs of the P-type MOS transistor QP3 is a voltage determined by (R1·I1). The present exemplary embodiment is configured such that the value of the current I1 is a constant value, and so setting such that I1·R1>Vt enables Vin=L to always be ON without the gate-source withstand voltage <Vgs> of the P-type MOS transistor QP3 ever being exceeded.

As described in detail above, the input circuit according to the present exemplary embodiment provides an input circuit enabling both an easing of withstand voltage-related constraints and an expansion in the input dynamic range to be achieved.

1. An input circuit comprising:
an input transistor including a drain input with an input voltage;
an input current generation circuit configured to generate an input current to flow in the input transistor;
a first resistor connected between a source of the input transistor and a first power source; and
an output transistor including a gate connected to a connection point between the source of the input transistor and the first resistor.

2. The input circuit of claim 1, wherein:
the input current generation circuit is configured by a current mirror circuit including a first transistor having a gate commonly connected to a gate of the input transistor, and a current source connected to a drain of the first transistor.

3. The input circuit of claim 1, further comprising a current mirror circuit configured by a second transistor having a drain commonly connected to a drain of the output transistor and a third transistor having a gate commonly connected to a gate of the second transistor, and a level shift circuit including a second resistor connected between a drain of the third transistor and a second power source having a lower voltage value than a voltage value of the first power source.

4. The input circuit of claim 2, further comprising a current mirror circuit configured by a second transistor having a drain commonly connected to a drain of the output transistor and a third transistor having a gate commonly connected to a gate of the second transistor, and a level shift circuit including a second resistor connected between a drain of the third transistor and a second power source having a lower voltage value than a voltage value of the first power source.
